(19) United States
(12) Patent Application Publication
(10) Pub. No.: US 2025/0343094 A1
(43) Pub. Date: Nov. 6, 2025

(54) POWER MODULE ASSEMBLY STRUCTURE

(71) Applicant: Delta Electronics, Inc., Taoyuan City (TW)

(72) Inventors: Jhen Ou Yang, Taoyuan City (TW); Hsin-Chun Chiang, Taoyuan City (TW); Hung-Nien Chiu, Taoyuan City (TW); Chun-Liang Chiang, Taoyuan City (TW); Fu-Yuan Shih, Taoyuan City (TW)

(21) Appl. No.: 19/085,523

(22) Filed: Mar. 20, 2025

Related U.S. Application Data
(60) Provisional application No. 63/642,307, filed on May 3, 2024.

(30) Foreign Application Priority Data
Aug. 2, 2024 (CN) 202411055603.1

(51) Int. Cl. H01L 23/367; H01L 23/373

(52) U.S. Cl. CPC H01L 23/367; H01L 23/3735

(57) ABSTRACT

A power module assembly structure is disclosed and includes a substrate, a semiconductor element, a base, a plurality of heat dissipation fins and a tin layer. The substrate includes a first metal surface and a second metal surface spatially opposite to each other. The semiconductor element is disposed on the first metal surface. The base includes a first surface and a second surface spatially opposite to each other. The plurality of heat dissipation fins are disposed on the second surface of the base. The tin layer is disposed between the second metal surface and the first surface of the base, so that the first surface of the base is close to the second metal surface. The base further includes a protruding step disposed on the first surface of the base, and the protruding step has a center aligned with the semiconductor element.

### CROSS-REFERENCE TO RELATED APPLICATION

This application claims the benefit of U.S. Provisional Application No. 63/642,307 filed on May 3, 2024, and entitled “FIN BASE WITH STAND-OFF BOSS”. This application claims priority to China Patent Application No. 202411055603.1, filed on Aug. 2, 2024. The entireties of the above-mentioned patent application are incorporated herein by reference for all purposes.

### FIELD OF THE INVENTION

The present disclosure relates to a power module assembly structure and more particularly to a power module assembly structure having cooling protruding-steps to replace a part of the tin layer with the high-thermal-conductivity material of the fin base, so that the thermal resistance is reduced effectively and the entire heat dissipation efficiency is increased.

### BACKGROUND OF THE INVENTION

As the operating frequency and the operating current of power modules are increased continuously, the heat generated by the semiconductor elements per unit volume is increased accordingly. Since the heat dissipation areas of the traditional simple aluminum extrusion and the die-cast heat dissipation fins are limited due to mechanical processing, the area for exchanging heat with the surrounding air is not large. Even if equipped with a fan, the generated heat cannot be dissipated in a timely and sufficient manner, and it is not suitable for heat dissipation of power modules. Therefore, most common heat dissipation methods for power modules are liquid-cooling heat dissipation.

In the prior art, tin sheets are mainly used in the heat dissipation assembly structure of the power module to weld the power module and the heat dissipation fins. Then, the coolant is directly contacted with the fins. When the semiconductor element generates the heat, the generated heat is transferred to the heat dissipation fins on the lower surface, and then the coolant flows through the heat dissipation fins on the lower surface to remove the heat.

Under the prior assembly structure, the tin layer combining the power module and the heat dissipation fin needs to be welded with sufficient strength. However, due to the poor thermal conductivity of the tin layer, the heat emitted from the semiconductor elements on the upper surface of the heat dissipation base cannot be quickly transferred to the heat dissipation fins on the lower surface of the heat dissipation base for heat dissipation, and it results in poor heat dissipation effect of the heat dissipation base.

Therefore, there is a need of providing a power module assembly structure having cooling protruding-steps to replace a part of the tin layer with the high-thermal-conductivity material of the fin base. Thereby, the thermal resistance is effectively reduced, the entire heat dissipation efficiency is greatly increased, and the drawbacks encountered by the prior arts are obviated.

### SUMMARY OF THE INVENTION

An object of the present disclosure is to provide a power module assembly structure having cooling protruding-steps to replace a part of the tin layer with the high-thermal-conductivity material of the fin base. Thereby, the thermal resistance is reduced effectively and the entire heat dissipation efficiency is increased.

Another object of the present disclosure is to provide a power module assembly structure having cooling protruding-steps. When the semiconductor elements, the substrate, the tin layer and the fin base are stacked in sequence, an equal number of protruding steps are protruded and disposed on the top surface of the fin base facing the semiconductor elements to form an optimized heat dissipation path. Since the height of the protruding steps is smaller than the thickness of the original tin layer, a part of the tin layer is still arranged between the copper layer under the semiconductor elements and the fin base to maintain the bonding force of the tin layer. Furthermore, the thickness of the tin layer under the semiconductor elements is smaller than the thickness of the tin layer not under the semiconductor elements (i.e., the thickness of the original tin layer). In this way, the protruding steps formed of high-thermal-conductivity materials are used to replace the tin layer with limited thermal conductivity, and it helps to improve the heat dissipation performance of the area under the semiconductor elements. The number of protruding steps is the same as the number of semiconductor elements, and the protruding steps has a footprint equal to or similar to that of the semiconductor elements in view of the stacked direction. Preferably, the protruding steps are for example but not limited to square, rectangular, triangular, circular, elliptical or trapezoidal. Moreover, the horizontal cross-section of the protruding step is for example but not limited to rectangular, triangular, zigzag, trapezoidal or arc-shaped. Thereby, the thermal resistance of the copper layer, which is directly under the semiconductor elements and thermally coupled to the fin base through the tin layer, is reduced, and the bonding surface area of the protruding steps is increased. In other words, the arrangement of the protruding steps corresponding to the semiconductor elements not only forms an optimal heat dissipation path, but also helps to maintain the bonding strength between the copper layer of the power module and the fin base. Furthermore, the thickness of the tin layer welded between the copper layer of the power module and the fin base is ranged from 0.23 mm to 0.28 mm, and the height of the protruding steps is ranged from 0.15 mm to 0.25 mm. The maximum height of the protruding steps is limited to less than the thickness of the original tin layer. In that, the amount of tin layer used is reduced, the thermal resistance on the heat dissipation path is improved, but the bonding strength of the tin layer between the copper layer and the fin base is not reduced. Thus, the structural bonding strength of the power module assembly structure is maintained and the heat dissipation efficiency of the power module assembly structure is improved.

In accordance with an aspect of the present disclosure, a power module assembly structure is provided. The power module assembly structure includes a substrate, a semiconductor element, a base, a plurality of heat dissipation fins and a tin layer. The substrate includes a first metal surface and a second metal surface, wherein the first metal surface and the second metal surface are spatially opposite to each other. The semiconductor element is disposed on the first metal surface. The base includes a first surface and a second surface, wherein the first surface and the second surface are spatially opposite to each other. The plurality of heat dissipation fins are disposed on the second surface of the base. The tin layer is disposed between the second metal surface and the first surface of the base, so that the first surface of the base is close to the second metal surface, wherein the base further includes a protruding step disposed on the first surface of the base, and the protruding step has a center aligned with the semiconductor element.

In an embodiment, a footprint of the protruding step is greater than a footprint of the semiconductor element, and less than a footprint of the substrate.

In an embodiment, a footprint of the semiconductor element is greater than a footprint of the protruding step, and less than a footprint of the substrate.

In an embodiment, a footprint of the protruding step is equal to a footprint of the semiconductor element, and less than a footprint of the substrate.

In an embodiment, the semiconductor element, the substrate, the tin layer, the protruding step and the base are stacked sequentially along a first direction, and the protruding step is square, rectangular, triangular, circular, elliptical or trapezoidal in view of the first direction.

In an embodiment, the protruding step is rectangular, triangular, trapezoidal, serrated or arc-shaped in view of a second direction, and the second direction perpendicular to the first direction.

In an embodiment, the tin layer has a thickness varied with a height of the protruding step.

In an embodiment, the tin layer has a thickness arranged from 0.23 mm to 0.28 mm.

In an embodiment, the protruding step has a height arranged from 0.15 mm to 0.25 mm.

In an embodiment, the substrate is a direct-bonded-aluminum (DBA) ceramic substrate or a direct-bonded-copper (DBC) ceramic substrate.

In accordance with another aspect of the present disclosure, a power module assembly structure is provided. The power module assembly structure includes a substrate, a semiconductor element, a fin base and a tin layer. The substrate includes a first metal surface and a second metal surface, wherein the first metal surface and the second metal surface are spatially opposite to each other. The semiconductor element is disposed on the first metal surface. The fin base includes a first surface and a plurality of heat dissipation fins, wherein the first surface of the fin base is configured to attach to the second metal surface, and the plurality of heat dissipation fins are thermal coupled to the first surface. The tin layer is disposed between the second metal surface and the first surface of the fin base, so that the first surface of the fin base is close to the second metal surface, wherein the fin base further includes a protruding step disposed on the first surface of the fin base, the semiconductor element, the substrate, the tin layer, the protruding step and the fin base are stacked sequentially along a first direction, and the protruding step and the semiconductor element are at least partially overlapped in view of the first direction.

In an embodiment, a projection of the semiconductor element on the second metal surface is included in a projection of the protruding step on the second metal surface in view of the first direction.

In an embodiment, a projection of the protruding step on the second metal surface is included in a projection of the semiconductor element on the second metal surface in view of the first direction.

In an embodiment, a projection of the protruding step on the second metal surface and a projection of the semiconductor element on the second metal surface are overlapped with each other in view of the first direction.

In an embodiment, the protruding step has a bonding surface area greater than a projection of the protruding step on the second metal surface.

In an embodiment, the protruding step has a height less than a spaced distance between the second metal surface and the first surface.

In an embodiment, the power module assembly structure includes a number of semiconductor elements equal to a number of the protruding steps.

In an embodiment, the plurality of heat dissipation fins and the protruding step of the fin base are integrally formed on two opposite surfaces of the fin base.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a cross-sectional structural view illustrating a power module assembly structure according to a first embodiment of the present disclosure;

FIG. 2 is a cross-sectional structural view illustrating a power module assembly structure according to a second embodiment of the present disclosure;

FIG. 3 is a cross-sectional structural view illustrating a power module assembly structure according to a third embodiment of the present disclosure;

FIG. 4 is a cross-sectional structural view illustrating a power module assembly structure according to a fourth embodiment of the present disclosure;

FIG. 5 is a cross-sectional structural view illustrating a power module assembly structure according to a fifth embodiment of the present disclosure;

FIG. 6 is a cross-sectional structural view illustrating a power module assembly structure according to a sixth embodiment of the present disclosure;

FIG. 7 is a cross-sectional structural view illustrating a power module assembly structure according to a seventh embodiment of the present disclosure; and

FIG. 8 to FIG. 11 are top views illustrating different examples of the base with the protruding step in the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upward,” “downward,” “inner,” “outer” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second, and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

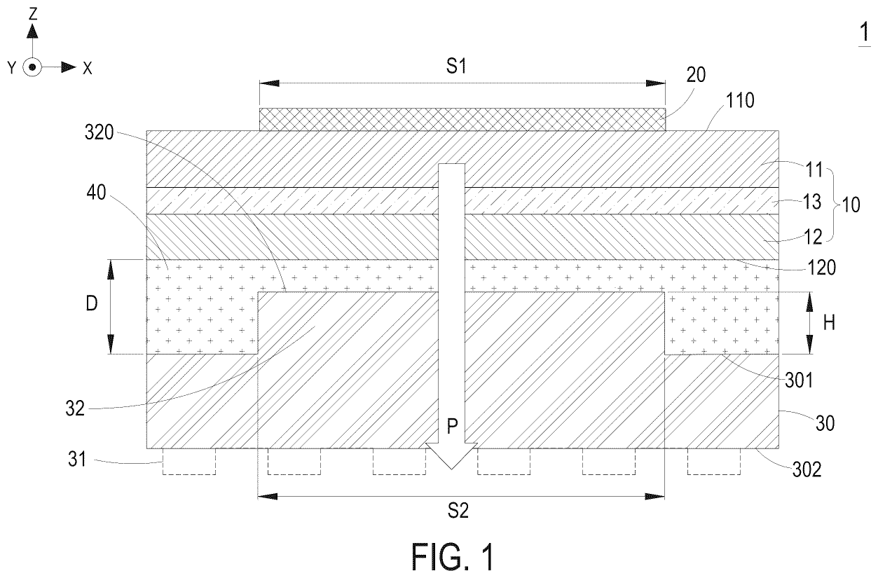

FIG. 1 is a cross-sectional structural view illustrating a power module assembly structure according to a first embodiment of the present disclosure. The present disclosure provides a liquid-cooled heat dissipation assembly structure suitable for a power module. The power module assembly structure 1 includes a substrate 10, a semiconductor element 20, a base (also called as a fin base) 30, a plurality of heat dissipation fins 31 and a tin layer 40. Preferably but not exclusively, the substrate 40 is a direct bonded aluminum (DBA) ceramic substrate or a direct-bonded-copper (DBC) ceramic substrate, which is formed by a first metal layer 11 and a second metal layer 12 sandwiching a ceramic layer 13. The substrate 10 includes a first metal surface 110 and a second metal surface 120. In the embodiment, the first metal surface 110 and the second metal surface 120 are spatially opposite to each other. Preferably but not exclusively, the first metal surface 110 and the second metal surface 120 are the opposite upper and lower surfaces of the substrate 10. Preferably but not exclusively, the semiconductor element 20 is a power chip. The semiconductor element 20 is disposed on the first metal surface 110 of the substrate 10. In the embodiment, the base 30 includes a first surface 301 and a second surface 302. The first surface 301 and the second surface 302 are spatially opposite to each other. Preferably but not exclusively, the first surface 301 and the second surface 302 are the opposite upper and lower surfaces of the base 30. The plurality of heat dissipation fins 31 are disposed on the second surface 302 of the base 30. In the embodiment, the base 30 further includes a protruding step 32 disposed on the first surface 301 of the base 30, and the protruding step 32 has a center aligned with the semiconductor element 20. Moreover, the number of protruding steps 32 is the same as the number of semiconductor elements 20. Notably, preferably but not exclusively, the base 30 is a liquid-cooled base (fin base), and a plurality of heat dissipation fins 31 and the protruding step 32 of base 30 are integrally formed on the second surface 302 and the first surface 301 of the base 30. The plurality of heat dissipation fins 31 on the second surface 302 can take away the heat by heat exchange with the coolant (not shown). Certainly, the present disclosure is not limited thereto. In the embodiment, the tin layer 40 is disposed between the second metal surface 120 of the substrate 10 and the first surface 301 of the base 30, so that the first surface 301 of the base 30 is close to the second metal surface 120 of the substrate 10.

In the embodiment, the semiconductor element 20, the substrate 10, the tin layer 40, the protruding step 32, the base 30 and the heat dissipation fins 31 are stacked sequentially from top to bottom along the first direction (i.e., the Z axial direction). A projection of the protruding step 32 on the second metal surface 120 and a projection of the semiconductor element 20 on the second metal surface 120 are at least overlapped with each other in view of the first direction (i.e., the Z axial direction). In the embodiment, a footprint S2 of the protruding step 32 is equal to a footprint S1 of the semiconductor element 20, and less than a footprint (not shown) of the substrate 10. Since the center of the protruding step 32 is aligned with the semiconductor element 20, the projection of the protruding step 32 on the second metal surface 120 is equal to the projection of the semiconductor element 20 on the second metal surface 120 are overlapped with each other in view of the first direction (i.e., the Z axial direction). In the embodiment, the substrate 10 and the base 30 are connected through soldering of the tin layer 40. Notably, in the embodiment, an equal number of protruding steps 32 are protruded on the first surface 301 of the base 30 to face the semiconductor elements 20, thereby forming an optimal heat dissipation path P. In the embodiment, a spaced distance D is formed between the second metal surface 120 of the substrate 10 and the first surface 301 of the base 30, and the tin layer 40 is filled therein, which is equal to an original thickness of the tin layer 40. In the embodiment, the spaced distance D or the thickness of the tin layer 40 is ranged from 0.23 mm and 0.28 mm. In addition, the protruding step 32 has a height H from the first surface 301 and the height H is ranged from 0.15 mm to 0.25 mm. In the embodiment, the height H of the protruding step 32 is limited to less than the spaced distance D from the second metal surface 120 to the first surface 301. Since the height H of the protruding step 32 is less than the thickness of the original tin layer 40 (i.e., the spaced distance D), a part of the tin layer 40 is arranged between the second metal layer 12 and the protruding step 30 directly to maintain the bonding force of the tin layer 40. Furthermore, the thickness of the tin layer 40 under the semiconductor element 20 (i.e., the difference between the spaced distance D and the height H) is smaller than the thickness of the tin layer 40 not under the semiconductor element 20 (i.e., the spaced distance D). In this way, the protruding step 32 formed of high-thermal-conductivity materials is used to replace the tin layer 40 with limited thermal conductivity, and it helps to improve the heat dissipation performance of the area under the semiconductor element 20. Thus, the optimal heat dissipation path P is formed to increase the entire heat dissipation efficiency.

On the other hand, in the embodiment, the protruding step 32 is rectangular in view of a second direction (i.e., the Y axial direction), and the second direction perpendicular to the first direction. Preferably but not exclusively, in other embodiments, the second direction is the X axial direction or the parallel direction on the XY plane, and the present disclosure is not limited thereto. In this way, the protruding step 32 further forms a bonding surface 320 on the first surface 301, including a top surface and four side walls. In other words, the bonding surface area of the bonding surface 320 is greater than the projection of the protruding step 32 on the second metal surface 120 (i.e., the footprint S2). The arrangement of the protruding step 32 corresponding to the semiconductor element 20 not only forms the optimal heat dissipation path P, but also increases the bonding surface area for welding the substrate 10 and the base 30. It helps to maintain the bonding strength between the second metal layer 12 of the substrate 10 and the base 30.

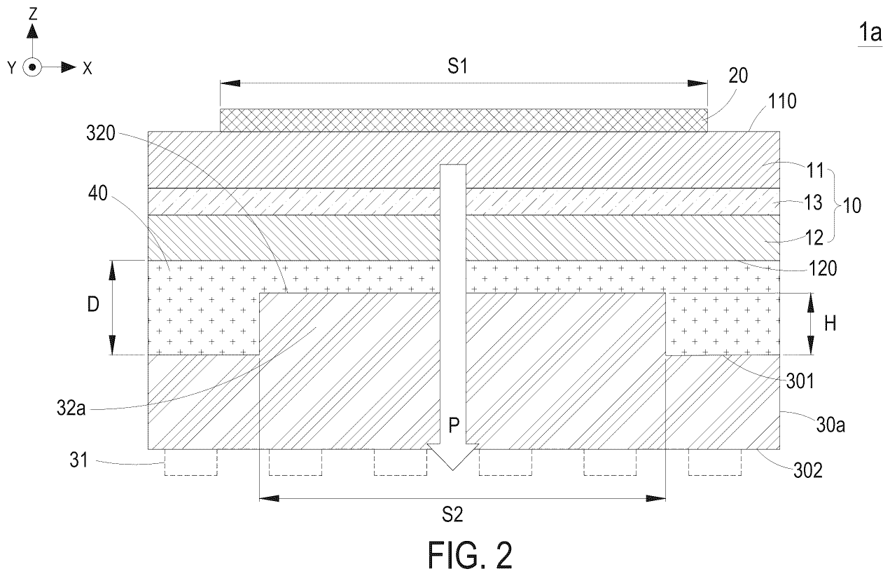

FIG. 2 is a cross-sectional structural view illustrating a power module assembly structure according to a second embodiment of the present disclosure. In the embodiment, the structures, elements and functions of the power module assembly structure la are similar to those of the power module assembly structure 1 of FIG. 1, and are not redundantly described herein. In the embodiment, the semiconductor element 20, the substrate 10, the tin layer 40, the protruding step 32a, the base 30 and the heat dissipation fins 31 are stacked sequentially from top to bottom along the first direction (i.e., the Z axial direction). A projection of the protruding step 32a on the second metal surface 120 is included in a projection of the semiconductor element 20 on the second metal surface 120 in view of the first direction (i.e., the Z axial direction). Namely, a footprint S2 of the protruding step 32a is less than a footprint S1 of the semiconductor element 20, and less than a footprint (not shown) of the substrate 10. Furthermore, in the embodiment, the protruding step 32a is rectangular in view of the second direction (i.e., the Y axial direction), and the protruding step 32a forms a bonding surface 320 on the first surface 301, so that the protruding step 32a has the bonding surface area greater than the footprint S2 of the protruding step 32a. Since the maximum height H of the protruding step 32a is limited to less than the thickness of the original tin layer 40 (i.e., the spaced distance D), the amount of tin layer 40 used is reduced, the thermal resistance on the heat dissipation path P is improved, but the bonding strength of the tin layer 40 between the second metal layer 12 and the base 30 is not reduced. Thus, the structural bonding strength of the power module assembly structure 1a is maintained and the heat dissipation efficiency of the power module assembly structure 1a is improved.

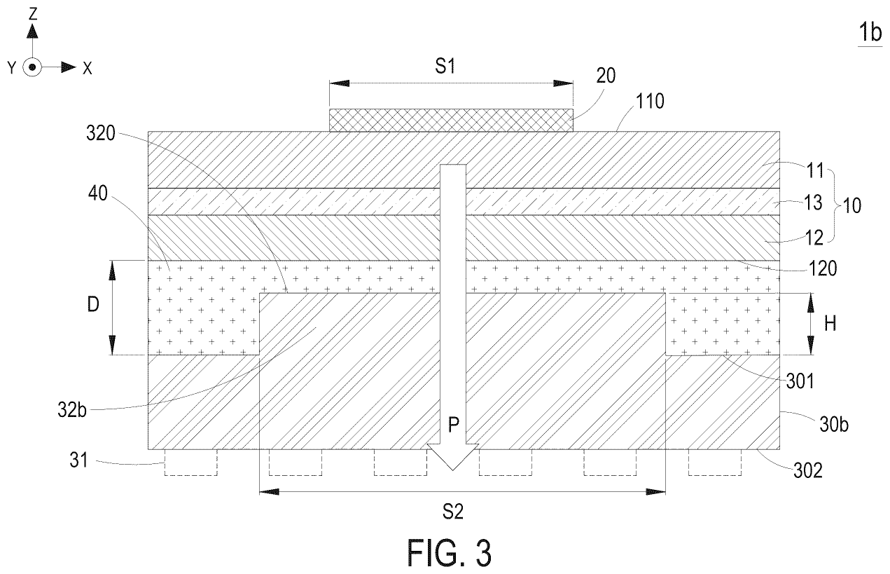

FIG. 3 is a cross-sectional structural view illustrating a power module assembly structure according to a third embodiment of the present disclosure. In the embodiment, the structures, elements and functions of the power module assembly structure 1b are similar to those of the power module assembly structure 1 of FIG. 1, and are not redundantly described herein. In the embodiment, the semiconductor element 20, the substrate 10, the tin layer 40, the protruding step 32b, the base 30 and the heat dissipation fins 31 are stacked sequentially from top to bottom along the first direction (i.e., the Z axial direction). A projection of the semiconductor element 20 on the second metal surface 120 is included in a projection of the protruding step 32b on the second metal surface 120 in view of the first direction (i.e., the Z axial direction). Namely, a footprint S2 of the protruding step 32b is greater than a footprint SI of the semiconductor element 20, and less than a footprint (not shown) of the substrate 10. Furthermore, in the embodiment, the protruding step 32b is rectangular in view of the second direction (i.e., the Y axial direction), and the protruding step 32b forms a bonding surface 320 on the first surface 301, so that the protruding step 32b has the bonding surface area greater than the footprint S2 of the protruding step 32b. Since the maximum height H of the protruding step 32b is limited to less than the thickness of the original tin layer 40 (i.e., the spaced distance D), the amount of tin layer 40 used is reduced, the thermal resistance on the heat dissipation path P is improved, but the bonding strength of the tin layer 40 between the second metal layer 12 and the base 30 is not reduced. Thus, the structural bonding strength of the power module assembly structure 1b is maintained and the heat dissipation efficiency of the power module assembly structure 1b is improved.

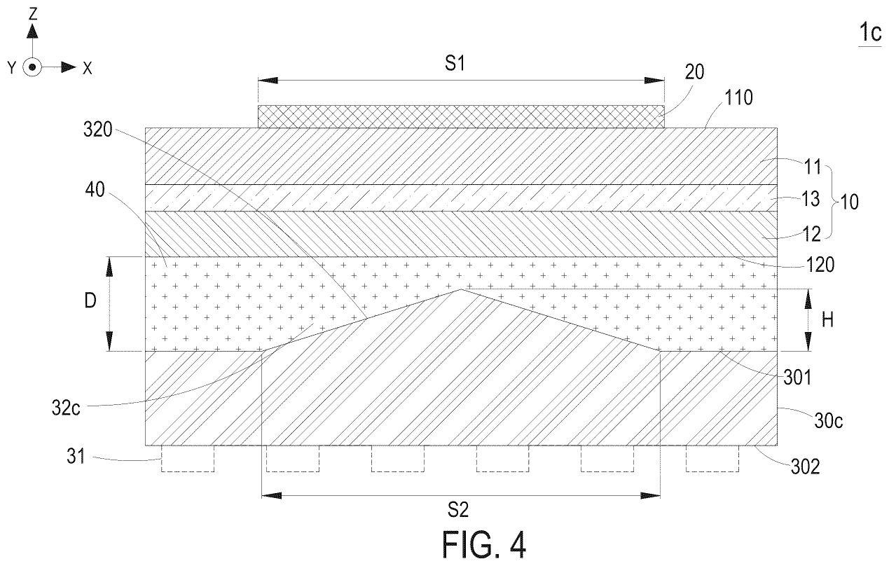

FIG. 4 is a cross-sectional structural view illustrating a power module assembly structure according to a fourth embodiment of the present disclosure. In the embodiment, the structures, elements and functions of the power module assembly structure 1c are similar to those of the power module assembly structure 1 of FIG. 1, and are not redundantly described herein. In the embodiment, the semiconductor element 20, the substrate 10, the tin layer 40, the protruding step 32c, the base 30 and the heat dissipation fins 31 are stacked sequentially from top to bottom along the first direction (i.e., the Z axial direction). A projection of the semiconductor element 20 on the second metal surface 120 and a projection of the protruding step 32c on the second metal surface 120 are overlapped with each other in view of the first direction (i.e., the Z axial direction). Namely, a footprint S2 of the protruding step 32c is equal to a footprint S1 of the semiconductor element 20, and less than a footprint (not shown) of the substrate 10. Furthermore, in the embodiment, the protruding step 32c is triangular in view of the second direction (i.e., the Y axial direction), and the protruding step 32c forms a bonding surface 320 on the first surface 301, so that the protruding step 32c has the bonding surface area greater than the footprint S2 of the protruding step 32c. Since the maximum height H of the protruding step 32c is limited to less than the thickness of the original tin layer 40 (i.e., the spaced distance D), when the tin layer 40 is pre-disposed between the first surface 301, the bonding surface 320 and the second metal surface 120, the thickness of the tin layer 40 is varied with the height H of the protruding step 32c. It helps to reduce the amount of the tin layer 40 and avoids generating the air gaps at the outer periphery of the protruding step 32c, so that the bonding strength of the tin layer 40 connected between the second metal layer 12 and the base 30 is not reduced. Thus, the structural bonding strength of the power module assembly structure 1c is maintained and the heat dissipation efficiency of the power module assembly structure 1c is improved.

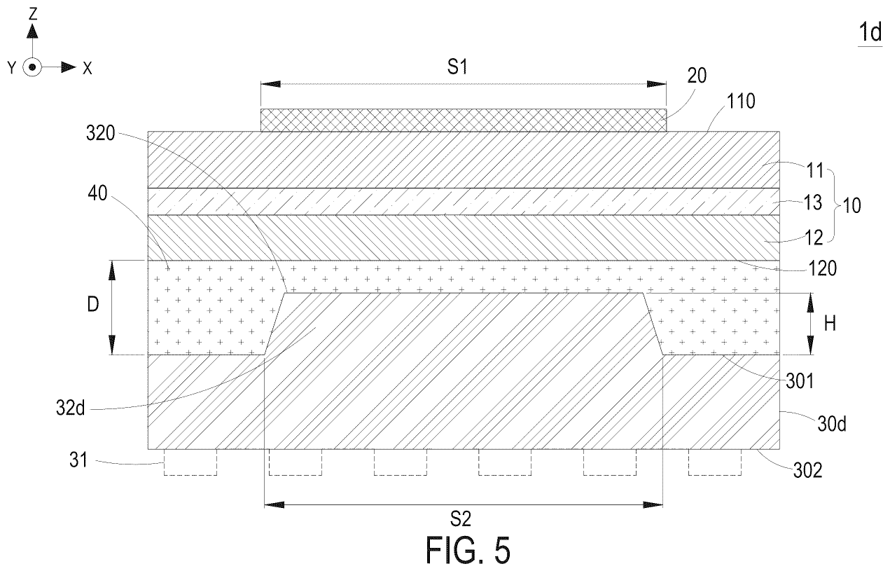

FIG. 5 is a cross-sectional structural view illustrating a power module assembly structure according to a fifth embodiment of the present disclosure. In the embodiment, the structures, elements and functions of the power module assembly structure Id are similar to those of the power module assembly structure 1c of FIG. 4, and are not redundantly described herein. In the embodiment, the semiconductor element 20, the substrate 10, the tin layer 40, the protruding step 32d, the base 30 and the heat dissipation fins 31 are stacked sequentially from top to bottom along the first direction (i.e., the Z axial direction). A projection of the semiconductor element 20 on the second metal surface 120 and a projection of the protruding step 32d on the second metal surface 120 are overlapped with each other in view of the first direction (i.e., the Z axial direction). Namely, a footprint S2 of the protruding step 32d is equal to a footprint SI of the semiconductor element 20, and less than a footprint (not shown) of the substrate 10. Furthermore, in the embodiment, the protruding step 32d is trapezoidal in view of the second direction (i.e., the Y axial direction), and the protruding step 32d forms a bonding surface 320 on the first surface 301, so that the protruding step 32d has the bonding surface area greater than the footprint S2 of the protruding step 32d. Since the maximum height H of the protruding step 32d is limited to less than the thickness of the original tin layer 40 (i.e., the spaced distance D), when the tin layer 40 is pre-disposed between the first surface 301, the bonding surface 320 and the second metal surface 120, the thickness of the tin layer 40 is varied with the height H of the protruding step 32d. It helps to reduce the amount of the tin layer 40 and avoids generating the air gaps at the outer periphery of the protruding step 32d, so that the bonding strength of the tin layer 40 connected between the second metal layer 12 and the base 30 is not reduced. Thus, the structural bonding strength of the power module assembly structure 1d is maintained and the heat dissipation efficiency of the power module assembly structure Id is improved.

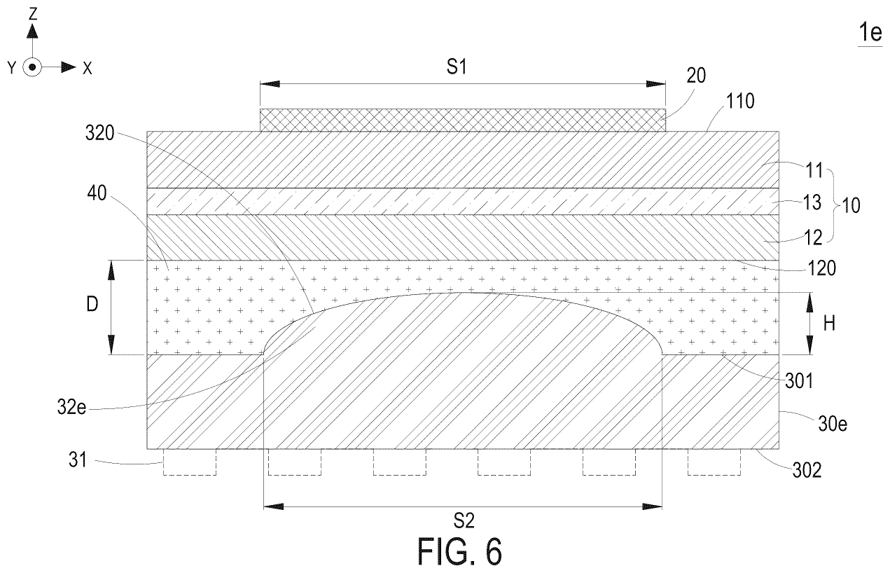

FIG. 6 is a cross-sectional structural view illustrating a power module assembly structure according to a sixth embodiment of the present disclosure. In the embodiment, the structures, elements and functions of the power module assembly structure le are similar to those of the power module assembly structure 1c of FIG. 4, and are not redundantly described herein. In the embodiment, the semiconductor element 20, the substrate 10, the tin layer 40, the protruding step 32e, the base 30 and the heat dissipation fins 31 are stacked sequentially from top to bottom along the first direction (i.e., the Z axial direction). A projection of the semiconductor element 20 on the second metal surface 120 and a projection of the protruding step 32e on the second metal surface 120 are overlapped with each other in view of the first direction (i.e., the Z axial direction). Namely, a footprint S2 of the protruding step 32e is equal to a footprint SI of the semiconductor element 20, and less than a footprint (not shown) of the substrate 10. Furthermore, in the embodiment, the protruding step 32e is arc-shaped in view of the second direction (i.e., the Y axial direction), and the protruding step 32e forms a bonding surface 320 on the first surface 301, so that the protruding step 32e has the bonding surface area greater than the footprint S2 of the protruding step 32e. Since the maximum height H of the protruding step 32e is limited to less than the thickness of the original tin layer 40 (i.e., the spaced distance D), when the tin layer 40 is pre-disposed between the first surface 301, the bonding surface 320 and the second metal surface 120, the thickness of the tin layer 40 is varied with the height H of the protruding step 32e. It helps to reduce the amount of the tin layer 40 and avoids generating the air gaps at the outer periphery of the protruding step 32e, so that the bonding strength of the tin layer 40 connected between the second metal layer 12 and the base 30 is not reduced. Thus, the structural bonding strength of the power module assembly structure le is maintained and the heat dissipation efficiency of the power module assembly structure le is improved.

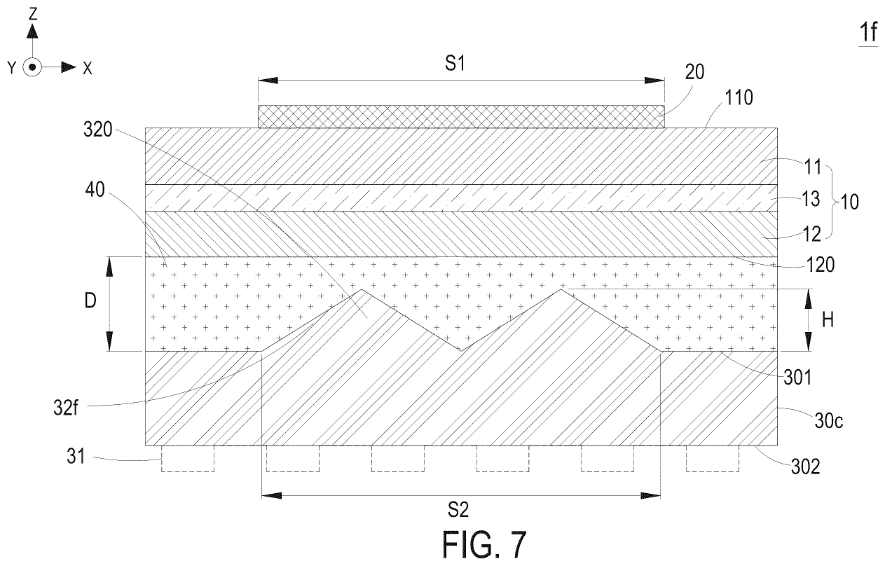

FIG. 7 is a cross-sectional structural view illustrating a power module assembly structure according to a seventh embodiment of the present disclosure. In the embodiment, the structures, elements and functions of the power module assembly structure If are similar to those of the power module assembly structure 1c of FIG. 4, and are not redundantly described herein. In the embodiment, the semiconductor element 20, the substrate 10, the tin layer 40, the protruding step 32f, the base 30 and the heat dissipation fins 31 are stacked sequentially from top to bottom along the first direction (i.e., the Z axial direction). A projection of the semiconductor element 20 on the second metal surface 120 and a projection of the protruding step 32f on the second metal surface 120 are overlapped with each other in view of the first direction (i.e., the Z axial direction). Namely, a footprint S2 of the protruding step 32f is equal to a footprint SI of the semiconductor element 20, and less than a footprint (not shown) of the substrate 10. Furthermore, in the embodiment, the protruding step 32f is serrated in view of the second direction (i.e., the Y axial direction), and the protruding step 32f forms a bonding surface 320 on the first surface 301, so that the protruding step 32f has the bonding surface area greater than the footprint S2 of the protruding step 32f. Since the maximum height H of the protruding step 32f is limited to less than the thickness of the original tin layer 40 (i.e., the spaced distance D), when the tin layer 40 is pre-disposed between the first surface 301, the bonding surface 320 and the second metal surface 120, the thickness of the tin layer 40 is varied with the height H of the protruding step 32f. It helps to reduce the amount of the tin layer 40 and avoids generating the air gaps at the outer periphery of the protruding step 32f, so that the bonding strength of the tin layer 40 connected between the second metal layer 12 and the base 30 is not reduced. Thus, the structural bonding strength of the power module assembly structure If is maintained and the heat dissipation efficiency of the power module assembly structure If is improved.

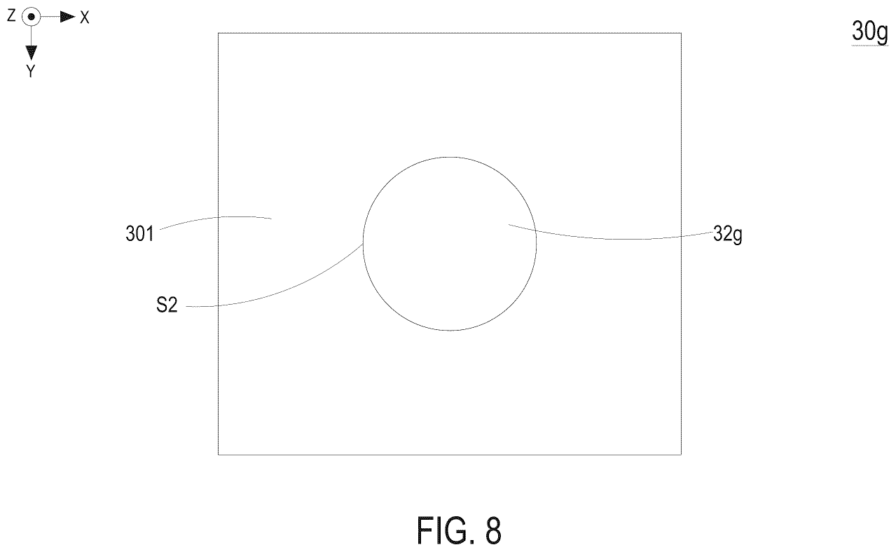

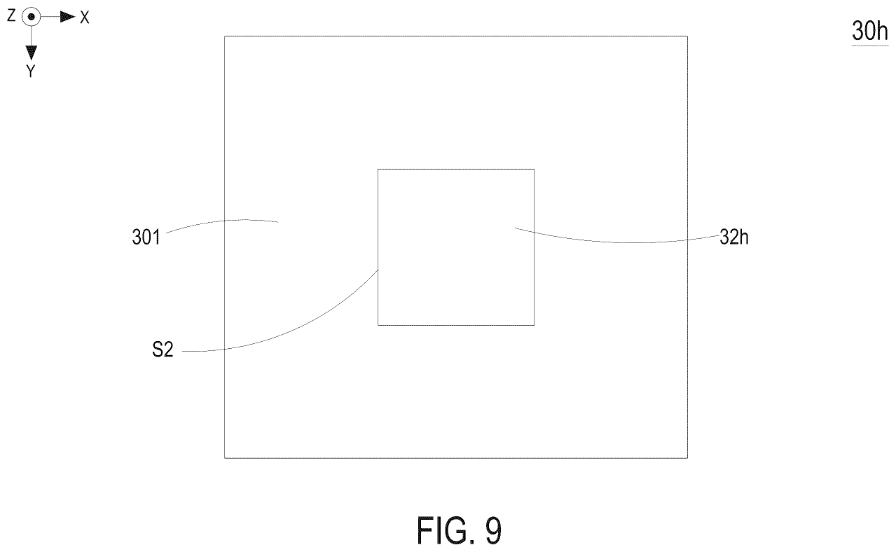

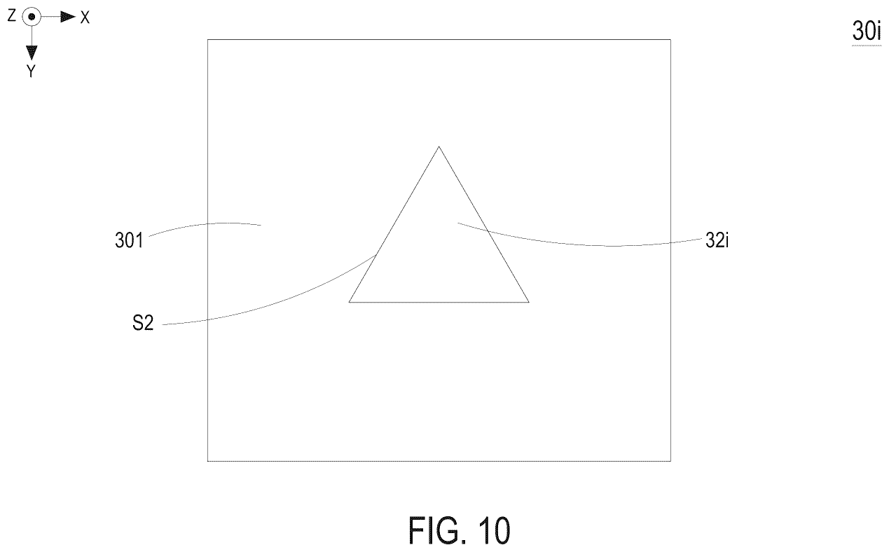

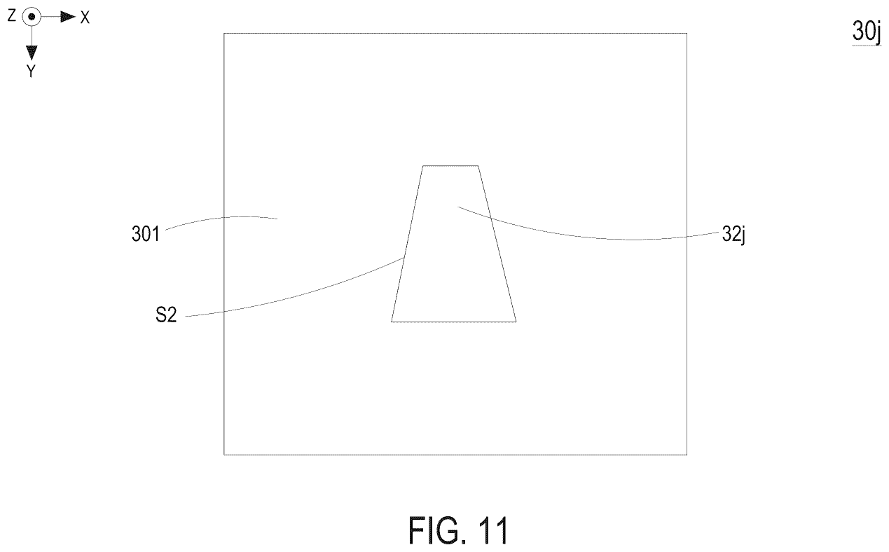

FIG. 8 to FIG. 11 are top views illustrating different examples of the base with the protruding step in the present disclosure. In the embodiments, the structures, elements and functions of the base 30g, 30h, 30i, 30j are similar to those of the base 30 of FIG. 1, and are not redundantly described herein. Please refer to FIG. 1 and FIG. 8 to FIG. 11. In an embodiment, the semiconductor element 20, the substrate 10, the tin layer 40, the protruding step 32g, the base 30g and the heat dissipation fins 31 are stacked sequentially from top to bottom along the first direction (i.e., the Z axial direction). Moreover, the protruding step 32g is circular (as shown in FIG. 8) in view of the first direction (i.e., the Z axial direction). Preferably but not exclusively, the footprint S2 of the protruding step 32g is similar to the footprint S1 of the semiconductor element 20. When the center of the protruding step 32g is aligned with the semiconductor element 20, the protruding step 32g is arranged between the substrate 10 and the base 30g, and a part of the tin layer 40 is replaced with the high-thermal-conductivity material of the fin base 30g. Thereby, the thermal resistance of the heat dissipation path is reduced effectively and the entire heat dissipation efficiency is increased. In another embodiment, the semiconductor element 20, the substrate 10, the tin layer 40, the protruding step 32h, the base 30h and the heat dissipation fins 31 are stacked sequentially from top to bottom along the first direction (i.e., the Z axial direction). Moreover, the protruding step 32h is square (as shown in FIG. 9) in view of the first direction (i.e., the Z axial direction). Preferably but not exclusively, the footprint S2 of the protruding step 32h is similar to the footprint SI of the semiconductor element 20. When the center of the protruding step 32h is aligned with the semiconductor element 20, the protruding step 32h is arranged between the substrate 10 and the base 30h, and a part of the tin layer 40 is replaced with the high-thermal-conductivity material of the fin base 30h. Thereby, the thermal resistance of the heat dissipation path is reduced effectively and the entire heat dissipation efficiency is increased. In an embodiment, the semiconductor element 20, the substrate 10, the tin layer 40, the protruding step 32i, the base 30i and the heat dissipation fins 31 are stacked sequentially from top to bottom along the first direction (i.e., the Z axial direction). Moreover, the protruding step 32i is triangular (as shown in FIG. 10) in view of the first direction (i.e., the Z axial direction). Preferably but not exclusively, the footprint S2 of the protruding step 32i is similar to the footprint SI of the semiconductor element 20. When the center of the protruding step 32i is aligned with the semiconductor element 20, the protruding step 32i is arranged between the substrate 10 and the base 30i, and a part of the tin layer 40 is replaced with the high-thermal-conductivity material of the fin base 30i. Thereby, the thermal resistance of the heat dissipation path is reduced effectively and the entire heat dissipation efficiency is increased. In another embodiment, the semiconductor element 20, the substrate 10, the tin layer 40, the protruding step 32j, the base 30j and the heat dissipation fins 31 are stacked sequentially from top to bottom along the first direction (i.e., the Z axial direction). Moreover, the protruding step 32j is trapezoidal (as shown in FIG. 11) in view of the first direction (i.e., the Z axial direction). Preferably but not exclusively, the footprint S2 of the protruding step 32j is similar to the footprint SI of the semiconductor element 20. When the center of the protruding step 32j is aligned with the semiconductor element 20, the protruding step 32j is arranged between the substrate 10 and the base 30j, and a part of the tin layer 40 is replaced with the high-thermal-conductivity material of the fin base 30j. Thereby, the thermal resistance of the heat dissipation path is reduced effectively and the entire heat dissipation efficiency is increased. Certainly, in other embodiments, the protruding step 32 can be for example but not limited to elliptical or in other symmetrical geometric shape in view of the first direction (i.e., the Z axial direction). When the center of the protruding step 32 is aligned with the semiconductor element 20, it allows to replace a part of tin layer 40 with the high-thermal-conductivity material of the fin base 30, so as to achieve the purposes of improving the structural strength and the heat dissipation efficiency. The present disclosure is not limited thereto, and not redundantly described hereafter.

In summary, the present disclosure provides a power module assembly structure having cooling protruding-steps to replace a part of the tin layer with the high-thermal-conductivity material of the fin base. Thereby, the thermal resistance is reduced effectively and the entire heat dissipation efficiency is increased. When the semiconductor elements, the substrate, the tin layer and the fin base are stacked in sequence, an equal number of protruding steps are protruded and disposed on the top surface of the fin base facing the semiconductor elements to form an optimized heat dissipation path. Since the height of the protruding steps is smaller than the thickness of the original tin layer, a part of the tin layer is still arranged between the copper layer under the semiconductor elements and the fin base to maintain the bonding force of the tin layer. Furthermore, the thickness of the tin layer under the semiconductor elements is smaller than the thickness of the tin layer not under the semiconductor elements (i.e., the thickness of the original tin layer). In this way, the protruding steps formed of high-thermal-conductivity materials are used to replace the tin layer with limited thermal conductivity, and it helps to improve the heat dissipation performance of the area under the semiconductor elements. The number of protruding steps is the same as the number of semiconductor elements, and the protruding steps has a footprint equal to or similar to that of the semiconductor elements in view of the stacked direction. Preferably, the protruding steps are for example but not limited to square, rectangular, triangular, circular, elliptical or trapezoidal. Moreover, the horizontal cross-section of the protruding step is for example but not limited to rectangular, triangular, zigzag, trapezoidal or arc-shaped. Thereby, the thermal resistance of the copper layer, which is directly under the semiconductor elements and thermally coupled to the fin base through the tin layer, is reduced, and the bonding surface area of the protruding steps is increased. In other words, the arrangement of the protruding steps corresponding to the semiconductor elements not only forms an optimal heat dissipation path, but also helps to maintain the bonding strength between the copper layer of the power module and the fin base. Furthermore, the thickness of the tin layer welded between the copper layer of the power module and the fin base is ranged from 0.23 mm to 0.28 mm, and the height of the protruding steps is ranged from 0.15 mm to 0.25 mm. The maximum height of the protruding steps is limited to less than the thickness of the original tin layer. In that, the amount of tin layer used is reduced, the thermal resistance on the heat dissipation path is improved, but the bonding strength of the tin layer between the copper layer and the fin base is not reduced. Thus, the structural bonding strength of the power module assembly structure is maintained and the heat dissipation efficiency of the power module assembly structure is improved.

While the disclosure has been described in terms of what is presently considered to be the most practical and preferred embodiments, it is intended to cover various modifications and similar arrangements included within the spirit and scope of the appended claims which are to be accorded with the broadest interpretation so as to encompass all such modifications and similar structures.

What is claimed is:

1. A power module assembly structure, comprising:
a substrate comprising a first metal surface and a second metal surface, wherein the first metal surface and the second metal surface are spatially opposite to each other;
a semiconductor element disposed on the first metal surface;
a base comprising a first surface and a second surface, wherein the first surface and the second surface are spatially opposite to each other;
a plurality of heat dissipation fins disposed on the second surface of the base; and
a tin layer disposed between the second metal surface and the first surface of the base, so that the first surface of the base is close to the second metal surface, wherein the base further includes a protruding step disposed on the first surface of the base, and the protruding step has a center aligned with the semiconductor element.

2. The power module assembly structure according to claim 1, wherein a footprint of the protruding step is greater than a footprint of the semiconductor element, and less than a footprint of the substrate.

3. The power module assembly structure according to claim 1, wherein a footprint of the semiconductor element is greater than a footprint of the protruding step, and less than a footprint of the substrate.

4. The power module assembly structure according to claim 1, wherein a footprint of the protruding step is equal to a footprint of the semiconductor element, and less than a footprint of the substrate.

5. The power module assembly structure according to claim 1, wherein the semiconductor element, the substrate, the tin layer, the protruding step and the base are stacked sequentially along a first direction, and the protruding step is square, rectangular, triangular, circular, elliptical or trapezoidal in view of the first direction.

6. The power module assembly structure according to claim 5, wherein the protruding step is rectangular, triangular, trapezoidal, serrated or arc-shaped in view of a second direction, and the second direction perpendicular to the first direction.

7. The power module assembly structure according to claim 1, wherein the tin layer has a thickness varied with a height of the protruding step.

8. The power module assembly structure according to claim 1, wherein the tin layer has a thickness arranged from 0.23 mm to 0.28 mm.

9. The power module assembly structure according to claim 1, wherein the protruding step has a height arranged from 0.15 mm to 0.25 mm.

10. The power module assembly structure according to claim 1, wherein the substrate is a direct-bonded-aluminum (DBA) ceramic substrate or a direct-bonded-copper (DBC) ceramic substrate.

11. A power module assembly structure, comprising:
a substrate comprising a first metal surface and a second metal surface, wherein the first metal surface and the second metal surface are spatially opposite to each other;
a semiconductor element disposed on the first metal surface;
a fin base comprising a first surface and a plurality of heat dissipation fins, wherein the first surface of the fin base is configured to attach to the second metal surface, and the plurality of heat dissipation fins are thermal coupled to the first surface; and
a tin layer disposed between the second metal surface and the first surface of the fin base, so that the first surface of the fin base is close to the second metal surface, wherein the fin base further includes a protruding step disposed on the first surface of the fin base, the semiconductor element, the substrate, the tin layer, the protruding step and the fin base are stacked sequentially along a first direction, and the protruding step and the semiconductor element are at least partially overlapped in view of the first direction.

12. The power module assembly structure according to claim 11, wherein a projection of the semiconductor element on the second metal surface is included in a projection of the protruding step on the second metal surface in view of the first direction.

13. The power module assembly structure according to claim 11, wherein a projection of the protruding step on the second metal surface is included in a projection of the semiconductor element on the second metal surface in view of the first direction.

14. The power module assembly structure according to claim 11, wherein a projection of the protruding step on the second metal surface and a projection of the semiconductor element on the second metal surface are overlapped with each other in view of the first direction.

15. The power module assembly structure according to claim 11, wherein the protruding step has a bonding surface area greater than a projection of the protruding step on the second metal surface.

16. The power module assembly structure according to claim 11, wherein the protruding step has a height less than a spaced distance between the second metal surface and the first surface.

17. The power module assembly structure according to claim 11, wherein the power module assembly structure includes a number of semiconductor elements equal to a number of the protruding steps.

18. The power module assembly structure according to claim 11, wherein the plurality of heat dissipation fins and the protruding step of the fin base are integrally formed on two opposite surfaces of the fin base.
